(19) United States
(12) Patent Application Publication
(10) Pub. No.: US 2024/0071759 A1
(43) Pub. Date: Feb. 29, 2024

(54) Confined Growth of 2D Materials and Their Heterostructures

(71) Applicant: Massachusetts Institute of Technology, Cambridge, MA (US)

(72) Inventors: Jeehwan Kim, Cambridge, MA (US); Kiseok Kim, Cambridge, MA (US); Sanghoon Bae, Cambridge, MA (US)

(73) Assignee: Massachusetts Institute of Technology, Cambridge, MA (US)

(21) Appl. No.: 18/238,853

(22) Filed: Aug. 28, 2023

Related U.S. Application Data
(60) Provisional application No. 63/374,090, filed on Aug. 31, 2022.

(51) Int. Cl. H01L 21/02

(52) U.S. Cl. CPC H01L 21/02554; H01L 21/02557; H01L 21/0256; H01L 21/02639

(57) ABSTRACT

Two-dimensional (2D) materials and their heterostructures show a promising path for next generation electronics. Nevertheless, there are challenges with (i) controlling monolayer (ML)-by-ML 2D material growth, (ii) maintaining single-domain growth, and (iii) controlling the number of layers and crystallinity at the wafer-scale. The deterministic confined growth techniques disclosed here address these challenges simultaneously to produce wafer-scale single-domain 2D MLs and their heterostructures on arbitrary substrates. The growth of the first nuclei is confined by patterning SiO₂ masks on 2-inch substrates to define selective or confined growth areas. Each growth area or trench is just a few microns wide and is filled with a single-domain ML before the second set of nuclei is introduced. Growing the second set of nuclei within the trenches yields an array of single-domain bilayers at the 2-inch wafer scale. Devices made with the single-domain bilayers exhibit excellent performance over the entire wafer.

### CROSS-REFERENCE TO RELATED APPLICATION(S)

This application claims the priority benefit, under 35 U.S.C. 119(e), of U.S. Application No. 63/374,090, filed Aug. 31, 2022, which is incorporated herein by reference in its entirety for all purposes.

### BACKGROUND OF THE INVENTION

Two-dimensional (2D) transition metal dichalcogenides (TMDs) and their heterostructures are a promising platform for next-generation electronics, spintronics, valleytronics, and optoelectronics. So far, however, the integration of semiconducting 2D heterostructures onto industrial platforms has been challenging because of limited scalability. A common method of constructing 2D heterostructures is mechanical exfoliation and stacking of 2D flakes, which is a trial-and-error-based operation, and thus suffers from severe size limits on the structures that can be produced. It also takes a long time to make 2D heterostructures using mechanical exfoliation and stacking.

Recently, substantial progress has been made in improving scalability using an epitaxial growth method to obtain single-crystalline monolayer (ML) TMDs on single-crystalline hexagonal substrates, such as sapphire. However, there still exist major challenges in growing large-scale 2D heterostructures due to the lack of strategies for layer-by-layer growth of single-domain TMDs. Moreover, some current growth methods involve the undesirable steps of infusing 2D materials into silicon devices as they are grown on hexagonal, non-silicon substrates. Single-domain TMD arrays can also be grown through laser irradiation of the nucleation spots. However, there are challenges with growth through laser irradiation because the second hetero-layer is likely to be nucleated at the edge of the first single-domain patches. To date, there is no feasible solution for obtaining single-domain 2D heterostructures at wafer scale.

### SUMMARY OF THE INVENTION

The present technology involves layer-by-layer growth of 2D materials on arbitrary substrates. These techniques can be used to grow single-domain homojunction and heterojunction TMDs at wafer scale. They also include non-epitaxy strategies for growing single-domain TMDs on amorphous materials, thus enabling single-crystalline 2D materials on a Si wafer coated with an arbitrary layer.

The present technology addresses fundamental kinetic issues in TMD growth. A SiO₂ mask on an amorphous Al₂O₃ or HfO₂ layer, which is on a Si substrate, confines the growth of the first set of TMD nuclei to an array of selective growth areas, called pockets or trenches, whose lateral dimensions (width and length) are no more than a few microns each. Density functional theory (DFT) calculations confirm higher TMD binding energy on those substrates than on the SiO₂ mask. As a result, the nucleation of the TMDs is concentrated on the substrate surface rather than on the walls of the SiO₂ mask. The reduced size of the pockets or trenches in the SiO₂ mask substantially reduces the duration of the growth, yielding a fully filled (i.e., single domain completely fills one pocket) first set of nuclei within the incubation period for a second set of nuclei for a second layer of TMD.

Thus, the ML-TMD layer in each trench across the wafer is a single crystalline domain. The confined geometry allows precise control of the number of layers such that the TMD MLs can be grown on top of each other to fill up the trenches.

The present technology can be used to make single-domain, bilayer (BL)-WSe₂ at a 2-inch wafer scale by subsequent confined growth of WSe₂. FETs fabricated on arrays of single-domain WSe₂ over an entire 2-inch wafer exhibit performance close to the level of mechanically exfoliated WSe₂ flakes, e.g., effective mobility up to 72.8 cm²V⁻¹ s⁻¹ for ML-WSe₂ and 103.5 cm²V⁻¹ s⁻¹ for BL-WSe₂.

Moreover, these techniques can be used for layer-by-layer confined growth of MoS₂/WSe₂ heterostructures at wafer scale. Valley lifetime measurements on arrays of single-domain MoS₂/WSe₂ heterostructures are comparable to those obtained from single-domain flakes of TMDs. The inventive confined growth techniques enable the fabrication of single-domain ML-by-ML homo- or heterojunctions at the wafer-scale.

An inventive method of confined growth of a 2D material (e.g., TMD, such as MoS₂, MoSe₂, WS₂, or WSe₂) on a substrate (e.g., HfO₂ or amorphous Al₂O₃) having a first binding energy with the 2D material can be implemented as follows. A mask layer (e.g., SiO₂) with a second binding energy with the 2D material that is lower than the first binding energy is formed on the substrate. A trench is formed in the mask layer with sidewalls that surround an exposed portion of the substrate. A nucleus of the 2D material is disposed on the exposed portion of the substrate and grown into a single-domain monolayer of the 2D material. This single-domain monolayer may fill the trench. The single-domain monolayer can be used to form a semiconductor device, such as a valleytronics device, forksheet field-effect transistor (FET), or complementary FET.

The trench's maximum lateral dimension may be roughly equal to a product of an incubation time of another nucleus of the 2D material on the single-domain, monolayer and a growth rate of the 2D material. For example, the trench's maximum lateral dimension may be about 2 microns. The trench may be one of many trenches in an array of trenches formed in the mask layer, with a single nucleus of the 2D material deposited in each trench in the array of trenches. When the critical trench size in each pocket is at or below a threshold, such as 2 microns, the formation of such a single nucleus of the 2D material is obtained. These nuclei can be grown into respective single-domain monolayers of the 2D material filling the trenches in the array of trenches.

In some cases, the nucleus is a first nucleus and the single-domain monolayer is a first single-domain monolayer. In these cases, a second nucleus of the 2D material can be deposited on the first single-domain monolayer and grown into a second single-domain monolayer of the 2D material so as to form a bilayer of the 2D material in the trench. Alternatively in these cases, the 2D material is a first 2D material, and a nucleus of a second 2D material different than the first 2D material is deposited on the single-domain monolayer and grown to form a heterostructure of the first 2D material and the second 2D material in the trench. For example, the first and second 2D materials can each be picked from the group consisting of MoS₂, MoSe₂, WS₂, and WSe₂.

In one embodiment, the present invention provides a method comprising the steps of: (a) providing a substrate of a first material; (b) depositing a mask material on the substrate; (c) forming a trench array on the mask material, the trench array comprising a plurality of trenches, each trench having a trench geometry having lateral dimensions of l×w, where each of l and w is picked to have a maximum dimension of 2 μm and each trench having an exposed portion of the substrate surrounded by sidewalls formed of the mask material; (d) depositing an adatom of a second material on the exposed portion of the substrate, wherein a first binding energy between the first material and the second material is greater than a second binding energy between the mask material and the second material; (e) allowing the adatom to selectively nucleate into a nucleus within each trench in the trench array; and (f) growing the nucleus within each trench in the trench array; and wherein the lateral dimensions associated with the trench geometry limit growth of the nucleus to a single-domain monolayer of the second material.

In one embodiment, the first material comprises one of hafnium oxide (HfO₂), aluminum oxide (Al₂O₃), hafnium zirconium oxide (HZO), titanium dioxide (TiO₂), zinc oxide (ZnO), iron oxide (Fe₂O₃), tin oxide (SnO₂), nickel oxide (NiO), or copper oxide (CuO). In one embodiment, the second material comprises one of graphene, carbon nanotube (CNT), hexagonal boron nitride (h-BN), metallic transition-metal dichalcogenide (e.g., vanadium disulfide (VS₂), vanadium diselenide (VSe₂), cobalt sulfide (CoS₂), cobalt selenide (CoSe₂), titanium disulfide (TiS₂), or titanium diselenide (TiSe₂)), semiconducting transition-metal dichalcogenide (e.g., molybdenum disulfide (MoS₂), molybdenum diselenide (MoSe₂), tungsten disulfide (WS₂), or tungsten diselenide (WSe₂)), or high-k material (e.g., Bi₂SeO₅ or Sb₂O₃). In one embodiment, the mask material comprises at least one of amorphous silicon dioxide (a-SiO₂), amorphous silicon (a-Si), amorphous silicon nitride (a-SiNₓ), amorphous carbon (a-carbon), hafnium oxide (HfO₂), aluminum oxide (Al₂O₃), hafnium zirconium oxide (HfZrO), titanium dioxide (TiO₂), zinc oxide (ZnO), iron oxide (Fe₂O₃), tin oxide (SnO₂), nickel oxide (NiO), or copper oxide (CuO).

In one extended embodiment, wherein the nucleus is a first nucleus and the single-domain monolayer is a first single-domain monolayer, the method further comprising the steps of: (g) waiting for an incubation period; (h) depositing another adatom of a third material on top of the first single-domain monolayer of at least one trench in the trench array, wherein a third binding energy between the second material and the third material is greater than the second binding energy between the mask material and the third material; (i) allowing the another adatom of the third material to selectively nucleate into a second nucleus on top of the first single-domain monolayer within the at least one trench in the trench array; and (j) growing the nucleus within the at least one trench in the trench array; and wherein the lateral dimensions associated with the trench geometry limit growth of the second nucleus to a second single-domain monolayer of the third material, and wherein the first single-domain monolayer and the second single-domain monolayer form a bilayer.

In one embodiment, the third material comprises one of graphene, carbon nanotube (CNT), hexagonal boron nitride (h-BN), metallic transition-metal dichalcogenide (e.g., vanadium disulfide (VS₂), vanadium diselenide (VSe₂), cobalt sulfide (CoS₂), cobalt selenide (CoSe₂), titanium disulfide (TiS₂), or titanium diselenide (TiSe₂)), semiconducting transition-metal dichalcogenide (e.g., molybdenum disulfide (MoS₂), molybdenum diselenide (MoSe₂), tungsten disulfide (WS₂), or tungsten diselenide (WSe₂)), or high-k material.

In one embodiment, the bilayer is a heterojunction bilayer where the second material and third material are different from each other. In another embodiment, the bilayer is a homojunction bilayer where the second material and third material are similar to each other.

In one embodiment, each of l and w are picked to have a value equal to a product of an incubation time of another nucleus of the second material on the single-domain monolayer and a growth rate of the second material. In another embodiment, each of l and w are picked to be 2 microns.

In another embodiment, the method further comprises the step of forming a semiconductor device (a valleytronics device, a forksheet field-effect transistor (FET), or a complementary FET) comprising the single-domain monolayer.

In one embodiment, before depositing the mask material on the substrate, the method comprises the step of depositing at least one of hafnium oxide (HfO₂), aluminum oxide (Al₂O₃), hafnium zirconium oxide (HZO), titanium dioxide (TiO₂), zinc oxide (ZnO), iron oxide (Fe₂O₃), tin oxide (SnO₂), nickel oxide (NiO), or copper oxide (CuO) on silicon to form the substrate.

In another embodiment, the present invention provides a method comprising the steps of: (a) providing a substrate of a first material, the first material having a first Gibbs free energy; (b) depositing a mask material on the substrate, the mask material having a second Gibbs free energy, the second Gibbs free energy higher than the first Gibbs free energy; (c) forming a trench array on the mask material, the trench array comprising a plurality of trenches, each trench having a trench geometry having lateral dimensions of l×w, where each of l and w is picked to have a maximum dimension of 2 μm and each trench having an exposed portion of the substrate surrounded by sidewalls formed of the mask material; (d) depositing an adatom of a second material on the exposed portion of the substrate; (e) allowing the adatom to selectively nucleate into a first nucleus within each trench in the trench array; (f) growing the first nucleus within each trench in the trench array; wherein the lateral dimensions associated with the trench geometry limit growth of the first nucleus to a first single-domain monolayer of the second material; (g) waiting for an incubation period; (h) depositing another adatom of a third material on top of the first single-domain monolayer of at least one trench in the trench array; (i) allowing the another adatom of the third material to selectively nucleate into a second nucleus on top of the first single-domain monolayer within the at least one trench in the trench array; and (j) growing the nucleus within the at least one trench in the trench array; wherein the lateral dimensions associated with the trench geometry limit growth of the second nucleus to a second single-domain monolayer of the third material, wherein the first single-domain monolayer and the second single-domain monolayer form a bilayer.

In one embodiment, the first material comprises one of hafnium oxide (HfO₂), aluminum oxide (Al₂O₃), hafnium zirconium oxide (HZO), titanium dioxide (TiO₂), zinc oxide (ZnO), iron oxide (Fe₂O₃), tin oxide (SnO₂), nickel oxide (NiO), or copper oxide (CuO).

In one embodiment, either the second material or the third material comprises one of graphene, carbon nanotube (CNT), hexagonal boron nitride (h-BN), metallic transition-metal dichalcogenide (e.g., vanadium disulfide (VS₂), vanadium diselenide (VSe₂), cobalt sulfide (CoS₂), cobalt selenide (CoSe₂), titanium disulfide (TiS₂), or titanium diselenide (TiSe₂)), semiconducting transition-metal dichalcogenide (e.g., molybdenum disulfide (MoS₂), molybdenum diselenide (MoSe₂), tungsten disulfide (WS₂), or tungsten diselenide (WSe₂)), or high-k material (e.g., Bi₂SeO₅ or Sb₂O₃).

In one embodiment, the mask material comprises at least one of amorphous silicon dioxide (a-SiO₂), amorphous silicon (a-Si), amorphous silicon nitride (a-SiNₓ), amorphous carbon (a-carbon), hafnium oxide (HfO₂), aluminum oxide (Al₂O₃), hafnium zirconium oxide (HfZrO), titanium dioxide (TiO₂), zinc oxide (ZnO), iron oxide (Fe₂O₃), tin oxide (SnO₂), nickel oxide (NiO), or copper oxide (CuO).

All combinations of the foregoing concepts and additional concepts discussed in greater detail below (provided such concepts are not mutually inconsistent) are part of the inventive subject matter disclosed herein. In particular, all combinations of claimed subject matter appearing at the end of this disclosure are part of the inventive subject matter disclosed herein. The terminology used herein that also may appear in any disclosure incorporated by reference should be accorded a meaning most consistent with the particular concepts disclosed herein.

### BRIEF DESCRIPTION OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar elements).

FIG. 1A illustrates a conventional process for growing transition metal dichalcogenides (TMDs).

FIG. 1B illustrates an inventive confined-growth process for selective single-domain synthesis of single-domain ML TMD that addresses the limitations of conventional TMD growth processes.

FIG. 1C illustrates fabrication of single-domain MoS₂-WSe₂ heterostructures by confined growth of a second MoS₂ layer on the WSe₂ ML in each trench in an array of trenches.

FIG. 1D shows a calculation of binding energy of W₃O₉, Se₂, and W₃Se₆ clusters on c-Al₂O₃, a-HfO₂, and a-SiO₂ substrates.

FIGS. 2A-2D show selective single-domain synthesis and ML-by-ML confined growth of WSe₂ in 10 μm (FIGS. 2A and 2B) and 2 μm (FIGS. 2C and 2D) pockets on sapphire substrates with SiO₂ sidewalls.

FIGS. 2E-2H show Raman and photoluminescence (PL) mapping images of confined ML-WSe₂ (FIGS. 2E and 2F) and bilayer (BL)-WSe₂ (FIGS. 2G and 2H) in 2 μm pockets on sapphire substrates.

FIG. 21 is a cross-sectional, high-resolution (HR) transmission electron microscope (TEM) image of confined ML-WSe₂ in a pocket on a sapphire substrate.

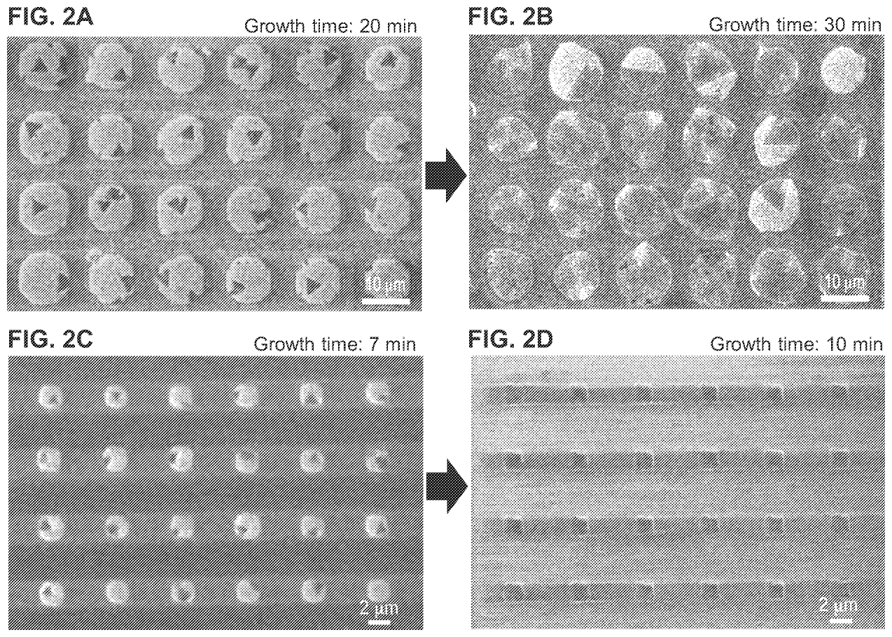

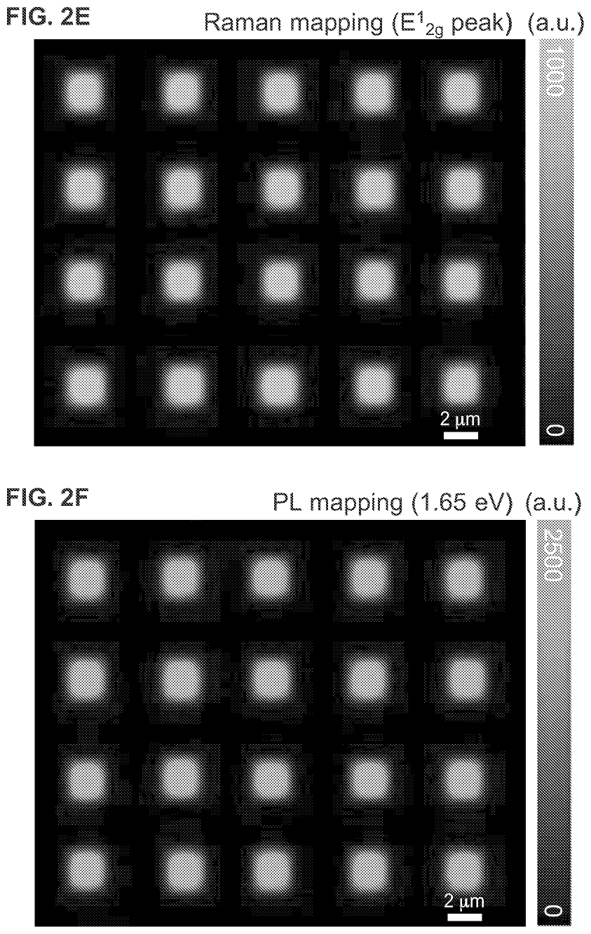

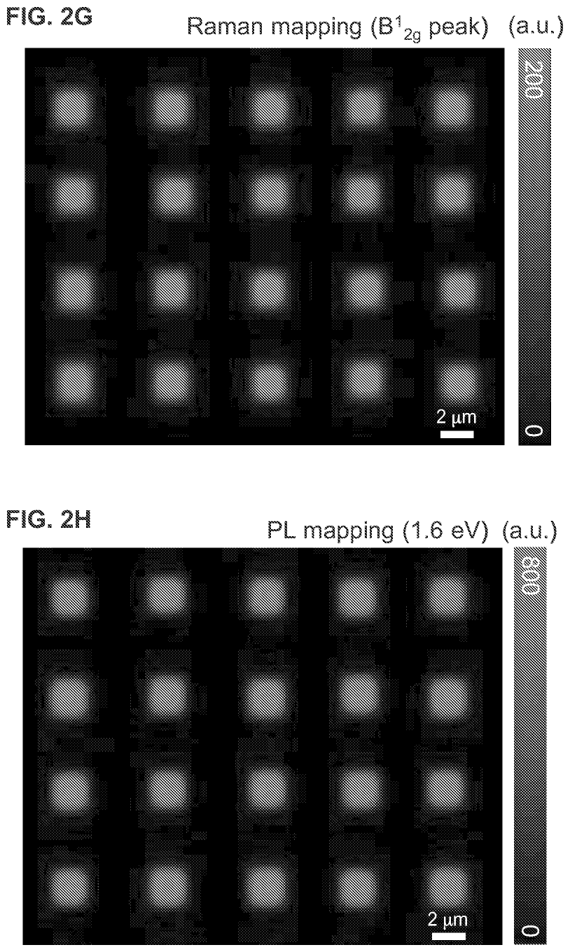

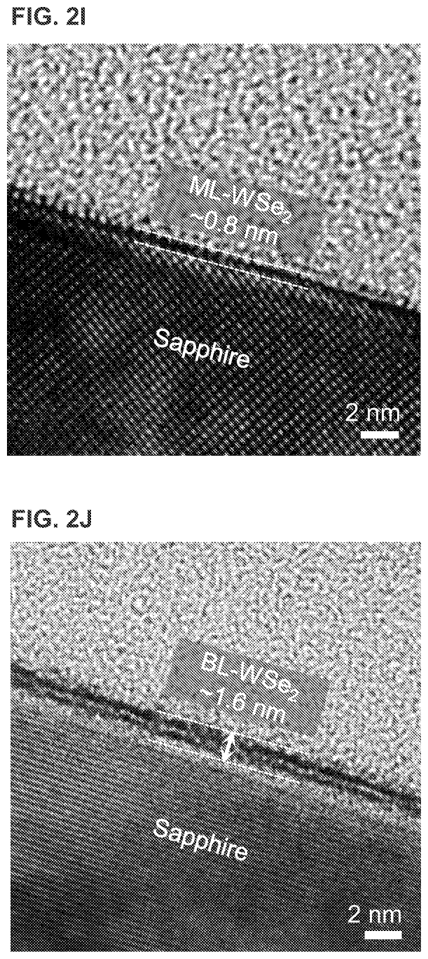

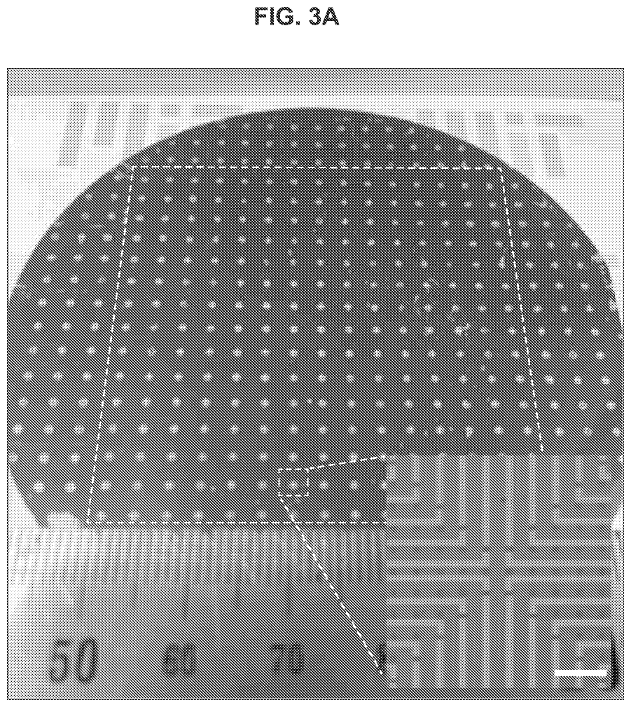

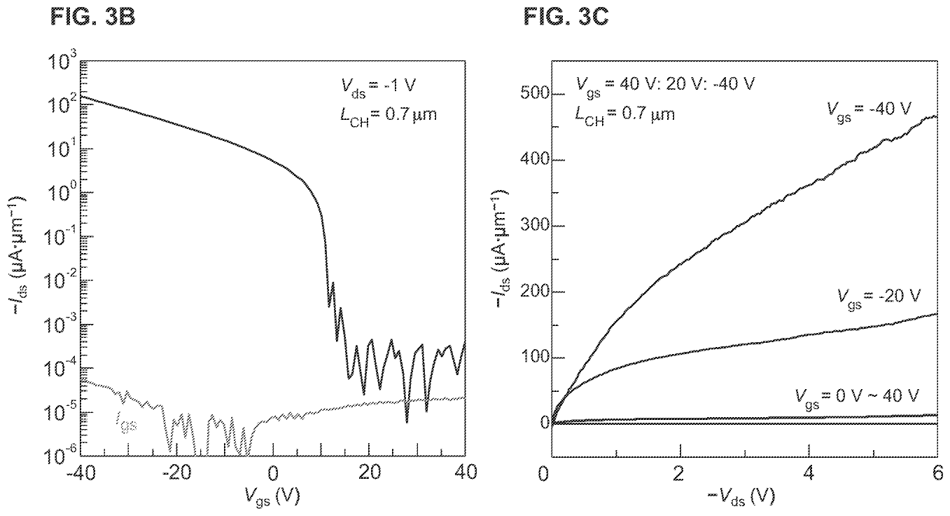

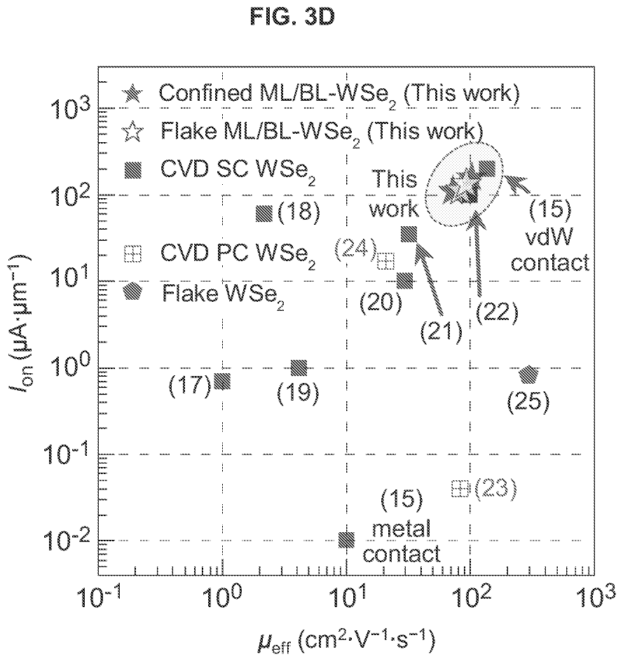

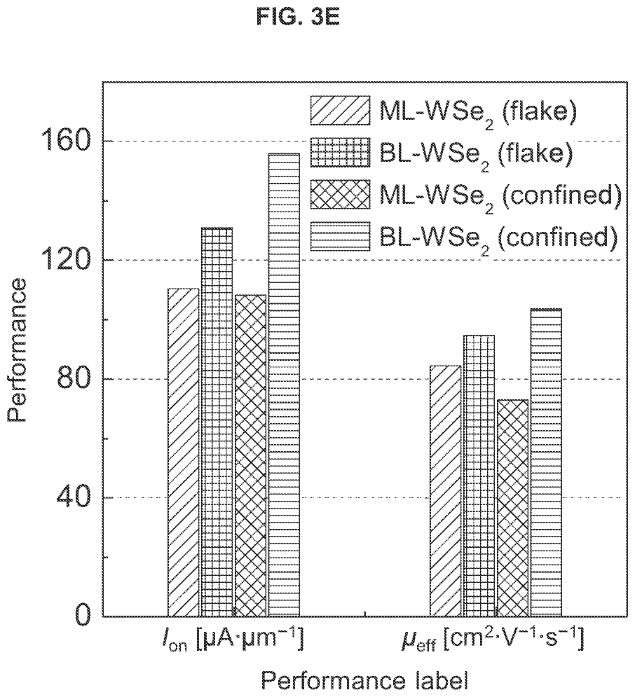

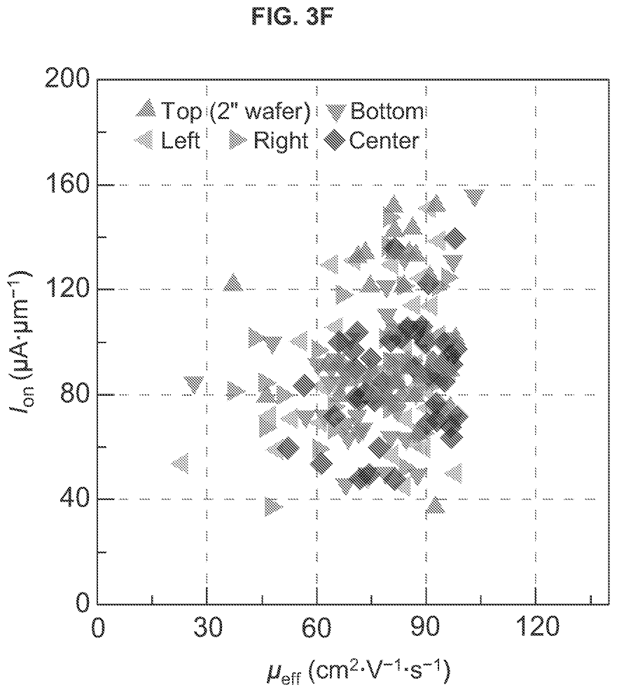

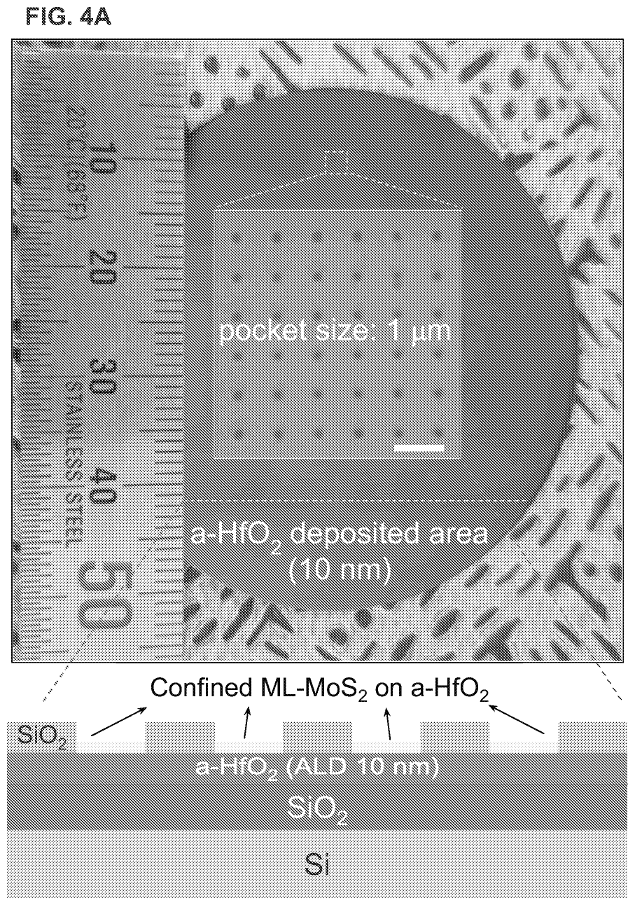

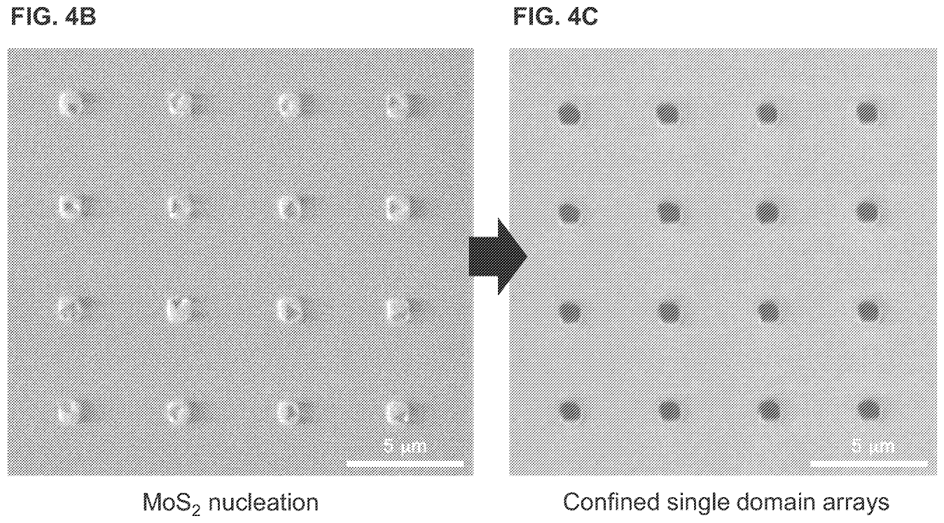

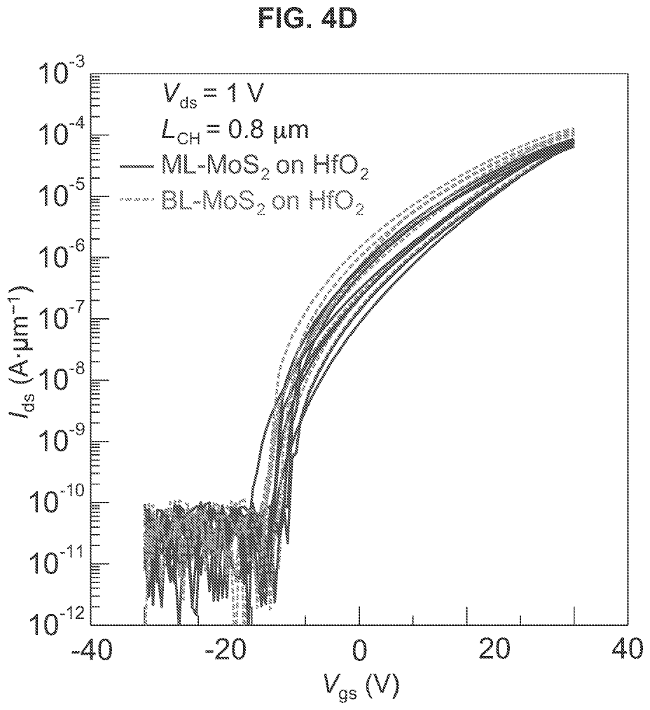

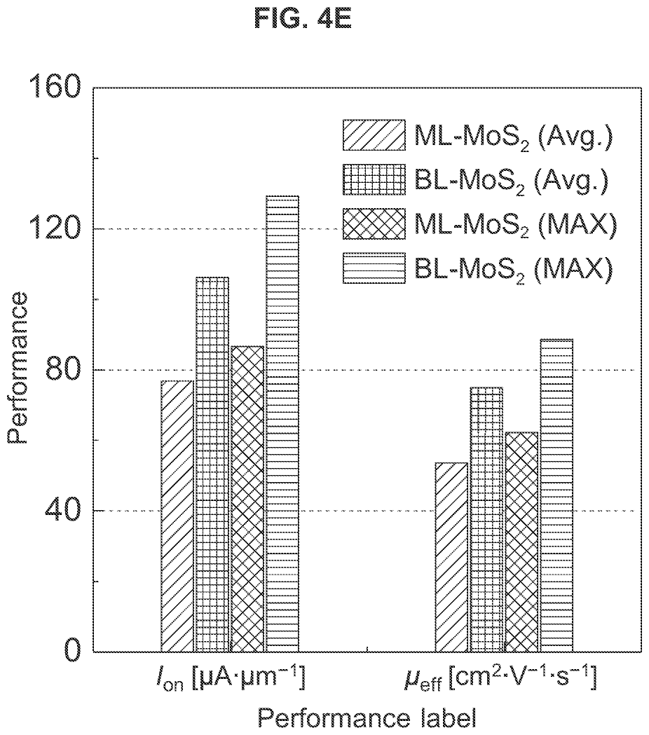

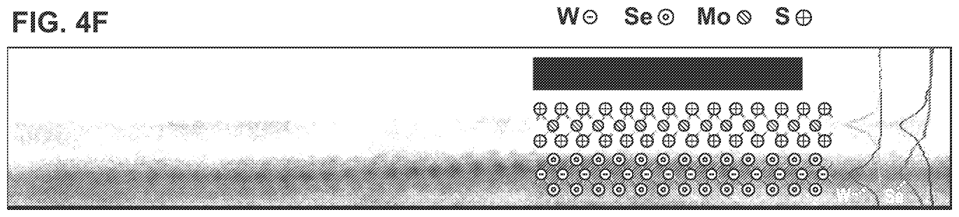

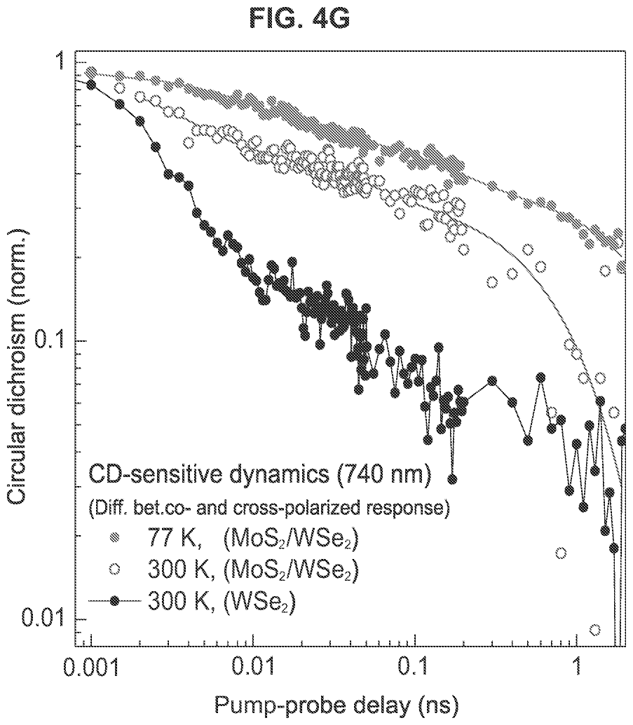

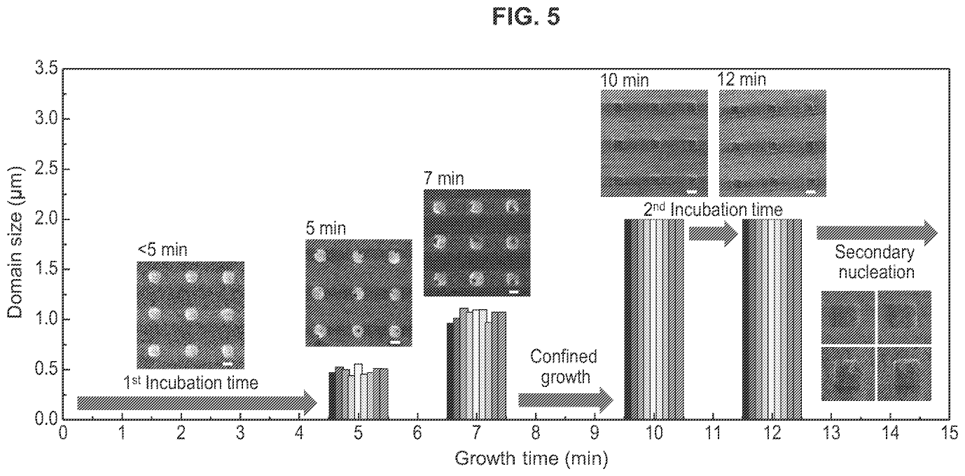

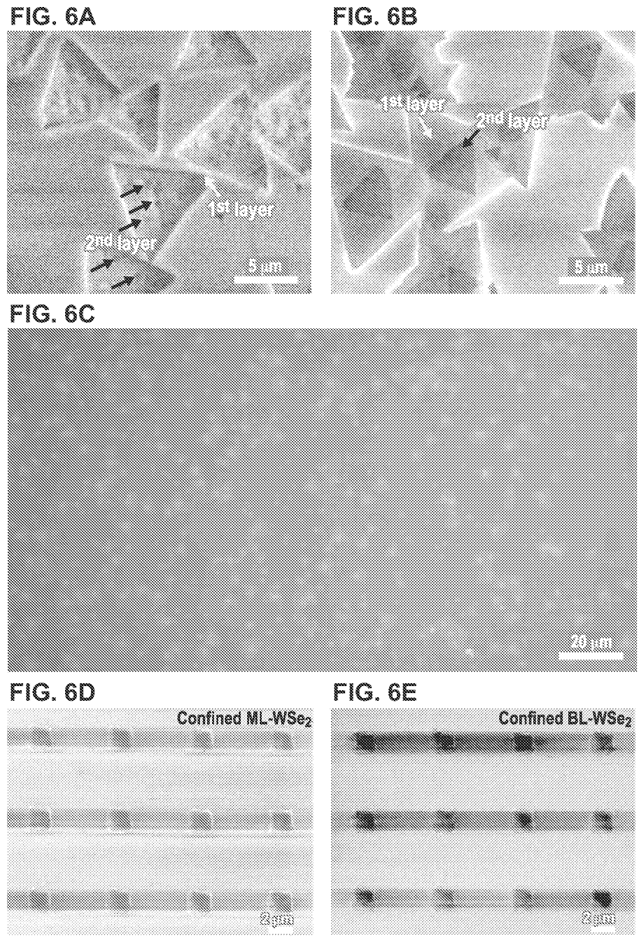

FIG. 2J is a cross-sectional, HR TEM image of confined BL-WSe₂ in a pocket on a sapphire substrate.

FIG. 3A is a photograph of integrated confined BL-WSe₂ field-effect transistor (FET) arrays on a SiO₂/Si wafer that is 5.1-cm-by-5.1-cm in size. The inset shows a micrograph of an individual FET array with 20 integrated FETs (scale bar: 10 μm).

FIG. 3B shows transfer characteristics of a confined BL-WSe₂ FET at a drain-source voltage V_{DS}=−1 V, where the channel length L_{CH} is 0.7 μm. The results show a maximum on-current density of up to 155.8 μA μm⁻¹ and a field-effect mobility of up to 103.5 cm² V⁻¹ s⁻¹.

FIG. 3C shows output characteristics of a confined BL-WSe₂ FET.

FIG. 3D shows on-current density Iₒₙ versus effective mobility par for different WSe₂ FETs, including inventive FETs (stars; upper right) and FETs with chemical vapor deposition (CVD) grown single-crystalline 1-3 ML-WSe₂ (filled dark squares), CVD grown poly-crystalline 1-3 ML-WSe₂ films (empty squares), and as-exfoliated WSe₂ flakes (pentagons). The drain-source voltage and channel length are −1 V and about 1 μm, respectively.

FIG. 3E is a histogram of on-current density Iₒₙ (left) and effective mobility μ_{eff} (right) for FETs fabricated with as-exfoliated ML/BL-WSe₂ flakes and confined ML/BL-WSe₂ films.

FIG. 3F is a plot of a statistical distribution with respect to on-current density and effective mobility for confined BL-WSe₂ FET arrays (the different triangles represent the positions of the BL-WSe₂ films on the wafer).

FIG. 4A shows a photograph and a schematic image of HfO₂ deposited on a Si wafer in a pocket with lateral dimensions of 1 μm (scale bar: 5 μm).

FIG. 4B shows nucleation of single-domain MoS₂ in 1 μm HfO₂ pockets with SiO₂ sidewalls.

FIG. 4C shows an array of confined single-domain MoS₂ in 1 μm HfO₂ pockets with SiO₂ sidewalls.

FIG. 4D is a plot of transfer characteristics of 16 FETs fabricated with confined ML-MoS₂ (8 FETs, lower traces) or BL-MoS₂ (8 FETs, upper traces) on HfO₂ substrates.

FIG. 4E is a histogram of average and maximum values of on-current density Ion (left) and effective mobility tiff (right) for ML-MoS₂ and BL-MoS₂ FETs.

FIG. 4F is a cross-sectional high-angle annular dark-field scanning transmission electron microscope (HAADF-STEM) image of a heterointerface [MoS₂ (upper layer) and WSe₂ (lower layer)] overlaid with the energy-dispersive X-ray (EDX) spectra for Mo Kα (upper left peak), S Kα (upper right peak), W Lα (lower left peak), and Se Kα (lower right peak).

FIG. 4G is a plot of the time-resolved circular dichroism (CD) response in ML-WSe₂ at 300 K (lower trace) and hetero-BL (MoS₂/WSe₂) at 300 K (middle trace) and 77 K (upper trace).

FIG. 5 depicts a plot showing the relationship between lateral growth rate and secondary nucleation time for confined growth.

FIGS. 6A through 6E illustrate a comparison of the formation of the second layer of WSe₂ with increasing H₂ content.

### DESCRIPTION OF THE PREFERRED EMBODIMENTS

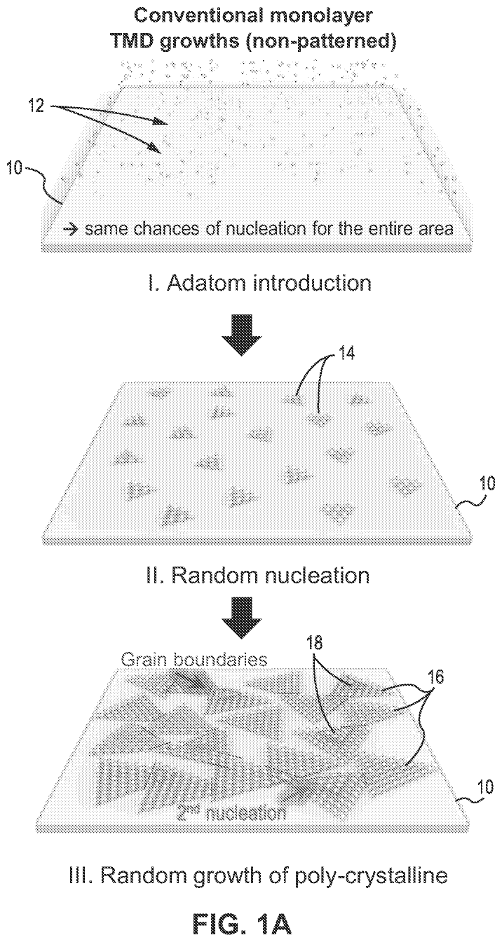

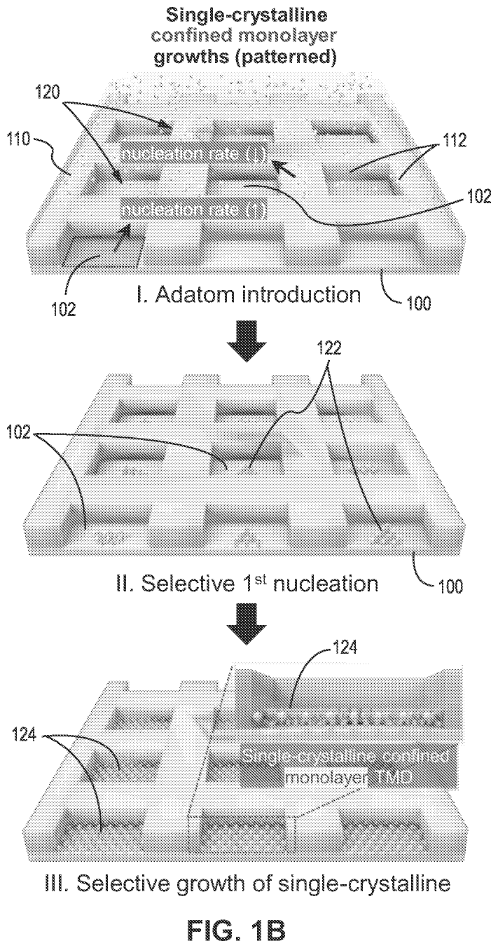

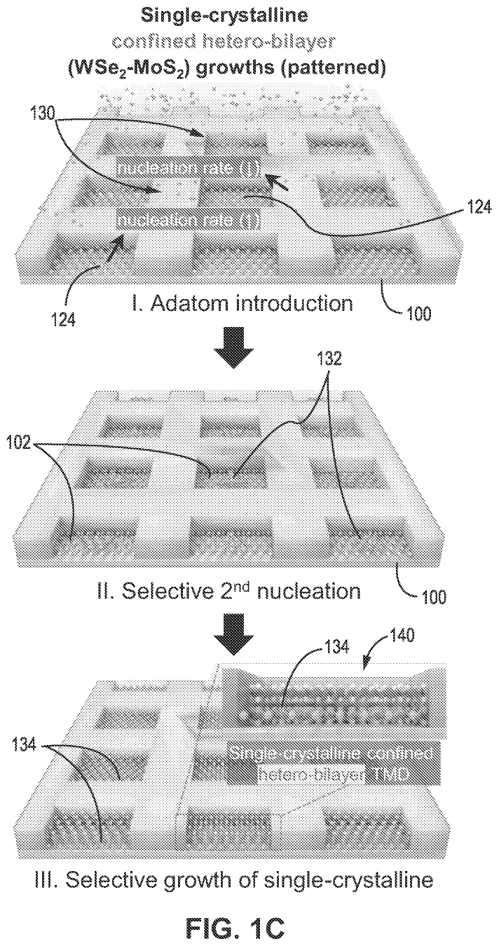

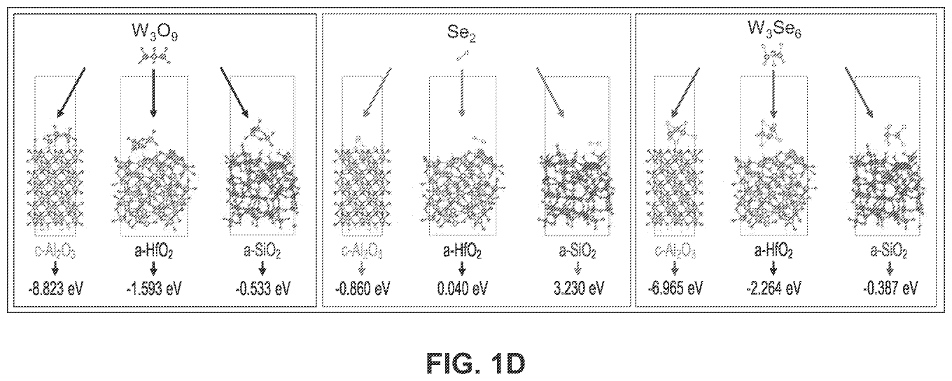

FIG. 1A shows a conventional transition metal dichalcogenide (TMD) growth process. Initially, a first set of TMD adatoms 12 is introduced onto the surface of a substrate (left). The TMD adatoms 12 nucleate to form nuclei 14 on the substrate 10. The orientations of these nuclei 14 are random as the nuclei 14 are not typically aligned with the substrate 10. While the nuclei 14 grow laterally to meet each other (middle), they form grains 16 that merge with each other, resulting in a continuous polycrystalline layer due to the random orientations of the nuclei 14. This polycrystalline growth eventually degrades the intrinsic properties of the TMDs. In addition, additional nucleation 18 may occur on some grains 16 (right). Without control of the additional nucleation, this process repeats, resulting in the growth of TMD layers with irregular thicknesses due to the overlapping grains 16 and nucleation of a second set of nuclei 18 on the initial layer of grains 16.

FIG. 1B illustrates a confined growth process that addresses these issues by precisely controlling the thickness and crystallinity of TMD growth. First, c-plane Al₂O₃, HfO₂, or another material with relatively low Gibbs free energy, such as amorphous or crystalline metal oxide, is deposited on Si wafers to form a substrate 100 upon which the TMD is grown. Other suitable substrate materials include graphene, hexagonal boron nitride (hBN), hafnium zirconium oxide (HZO), TiO₂, ZnO, Fe₂O₃, SnO₂, NiO, CuO, or TMD-coated materials.

Then a thin layer (e.g., 5 nm, 10 nm, 50 nm, 100 nm, or even hundreds of nanometers thick; possibly up to 250 nm, 500 nm, 750 nm, or 1 μm thick) of mask material 110 is coated onto the c-plane Al₂O₃ or HfO₂ surface of the substrate 100. Suitable mask materials include materials with relatively high Gibbs free energy, such as amorphous SiO₂ (a-SiO₂), a-Si, a-SiNₓ, and a-carbon.

Next, confined growth areas 102, also called recesses, pockets, trenches, wells, or cavities, each with lateral dimensions of tens of nanometers up to about 2 microns, are patterned in the thin layer 110 of a-SiO₂. The patterned a-SiO₂ layer 110 is also called a mask or mask layer. These pockets 102 can be any suitable shape (e.g., squares, rectangles, triangles, or circles) and can be formed in a 1D or 2D array (e.g., a square, rectangular, or hexagonal array). The pockets 102 can extend all the way through the a-SiO₂ layer 110 to expose a portion of the Al₂O₃ or HfO₂ surface of the substrate 100 surrounded by a-SiO₂ sidewalls 112. The pockets 102 may even extend partway (e.g., a few nanometers) into the c-plane Al₂O₃ or HfO₂ (FIG. 1B, left).

Once the pockets 102 have been formed in the a-SiO₂ layer 110, a 2D material adatom 120 is introduced into each pocket (left). As an example, it was noted that within a 1 nm×1 nm area, there are 42 (W and Se) adatoms. Accordingly, within a 2 μm×2 μm trench, for each pocket, there would be 84,000 adatoms required for a monolayer and 168,000 adatoms for a bilayer. Suitable 2D materials include semiconducting TMDs, such as WSe₂ (this example), MoS₂, MoSe₂, and WS₂. Other suitable 2D materials include but are not limited to graphene, carbon nanotubes (CNTs), hBN, metallic TMDs (e.g., VS₂, VSe₂, CoS₂, CoSe₂, TiS₂, TiSe₂), and high-k 2D materials (e.g., Bi₂SeO₅, Sb₂O₃).

The size of each pocket 102 is small enough that only a single nucleation (represented by a single triangle in FIG. 1B) 122 occurs in each pocket (middle). Each nucleation 122 grows on the exposed c-plane Al₂O₃ or HfO₂ at the bottom of its pocket 102 until it reaches the a-SiO₂ sidewalls 112 and fills up the entire trench 102 to form a TMD film 124 (right). Each TMD film 124 is single-domain and also a ML (right, inset).

FIG. 1C shows how the adatom introduction, nucleation, and single-crystalline growth steps of the process in FIG. 1B can be repeated to obtain single-domain MoS₂/WSe₂ heterostructures or single-domain homo-bilayers (BLs) of WSe₂. (A BL can be thought of as two MLs combined by van der Waals interaction.) Once MLs 124 of WSe₂ have been formed in the pockets 102, MoS₂ adatoms 130 are introduced into the cavities 102 on the WSe₂ MLs 124 (FIG. 1C, left). These MoS₂ adatoms 130 undergo nucleation to form nuclei 132 (middle) and growth (right) to form single-crystalline MoS₂ MLs 134 on the WSe₂ MLs 124 (right inset), resulting in a MoS₂/WSe₂ heterostructure 140 in each pocket 102. DFT calculations confirm this growth selectivity. Alternatively, WSe₂ adatoms can be deposited on the WSe₂ MLs and undergo nucleation and growth to form single-domain BLs of WSe₂.

FIG. 1D shows the binding energies of the WSe₂ precursors WO₃ and Se as well as the product WSe₂ clusters on c-Al₂O₃, a-HfO₂, and a-SiO₂ calculated from DFT. These DFT calculations show that WO₃ clusters (W₃O₉, left), Se clusters (Se₂, middle), and WSe₂ clusters (W₃Se₆, right) have stronger binding interactions with c-Al₂O₃ and a-HfO₂ than with the surface of SiO₂. This indicates that the clusters preferentially bind with the substrate surfaces at the bottoms of the pockets rather than the a-SiO₂ sidewalls of the pockets, leading to a selective WSe₂ growth within the pockets.

Simultaneous growth of WSe₂ on Al₂O₃, HfO₂, and SiO₂ substrates under the same CVD growth conditions confirm this selectivity. Atomic force microscopy (AFM) images show that WSe₂ nucleates only on the Al₂O₃ and HfO₂ instead of SiO₂ during 20 minutes of growth. This led to a successful selective confined growth of WSe₂ on the exposed substrate surface of the micropatterned SiO₂ trench arrays.

The trench size is selected to allow only single-domain, ML WSe₂ formation and depends on both the lateral growth rate of WSe₂ and the second nucleation incubation period. The measured lateral growth rate of WSe₂ and the incubation period of the second nucleation were ˜0.4 μm/minute and 5 minutes, respectively. This suggests that each trench should be no more than about 2 μm wide to avoid the nucleation of a second layer of WSe₂.

It is possible to control the lateral growth rate or incubation period (and hence the maximum trench width) by changing the content of TMD powder, gas ratio (Ar/H₂), and growth temperature. For example, such control may be affected by changing the content of S/Se powder between 100 mg to 1500 mg, or by changing the content of MoO₃/WO₃ powder between 10 mg to 100 mg. Also, the gas ratio of the percentage of Argon (Ar) to the percentage of hydrogen (H₂) may be adjustable between Ar-100%/H₂-0% and Ar-0%/H₂-100%. Also, the growth temperature may be adjustable between 200 C and 1000 C.

FIG. 5 depicts a plot showing the relationship between lateral growth rate and secondary nucleation time for confined growth. In this non-limiting example, after an initial incubation time of 5 minutes, WSe₂ was laterally grown up to 10 minutes, and secondary nucleation occurred after the confined monolayer (ML) was maintained for an additional 2 minutes (i.e., 2^{nd} incubation time of 2 minutes from the 10-minute point).

FIGS. 6A through 6E illustrate a comparison of the formation of the second layer of WSe₂ with increasing H₂ content. Scanning electron microscope images of second layer WSe₂, before (see FIG. 6A), and, after (see FIG. 6B) a 15% increase in H₂ content. FIG. 6C depicts an optical microscope image of AA′ stacking structure in FIG. 6B. An increase of H₂ saturates the nucleation density on the first ML-WSe₂, allowing the second layer WSe₂ to initiate nucleation at the center of the first ML. Therefore, the scanning electron microscope morphology of confined ML was compared with bilayer (BL) after ML-by-ML confined growth of WSe₂ at different H₂ contents (see FIGS. 6A and 6B). When compared to poly-crystalline WSe₂, the surface of confined WSe₂ was extremely smooth, and the contrast between the confined ML (see FIG. 6(d)) and the confined BL (see FIG. 6(e)) is similar.

In one embodiment, the present invention provides a method comprising the steps of: (a) providing a substrate of a first material; (b) depositing a mask material on the substrate; (c) forming a trench array on the mask material, the trench array comprising a plurality of trenches, each trench having a trench geometry having lateral dimensions of l×w, where each of l and w is picked to have a maximum dimension of 2 μm and each trench having an exposed portion of the substrate surrounded by sidewalls formed of the mask material; (d) depositing an adatom of a second material on the exposed portion of the substrate, wherein a first binding energy between the first material and the second material is greater than a second binding energy between the mask material and the second material; (e) allowing the adatom to selectively nucleate into a nucleus within each trench in the trench array; and (f) growing the nucleus within each trench in the trench array; and wherein the lateral dimensions associated with the trench geometry limit growth of the nucleus to a single-domain monolayer of the second material.

In one embodiment, the first material comprises one of hafnium oxide (HfO₂), aluminum oxide (Al₂O₃), hafnium zirconium oxide (HZO), titanium dioxide (TiO₂), zinc oxide (ZnO), iron oxide (Fe₂O₃), tin oxide (SnO₂), nickel oxide (NiO), or copper oxide (CuO). In one embodiment, the second material comprises one of graphene, carbon nanotube (CNT), hexagonal boron nitride (h-BN), metallic transition-metal dichalcogenide (e.g., vanadium disulfide (VS₂), vanadium diselenide (VSe₂), cobalt sulfide (CoS₂), cobalt selenide (CoSe₂), titanium disulfide (TiS₂), or titanium diselenide (TiSe₂)), semiconducting transition-metal dichalcogenide (e.g., molybdenum disulfide (MoS₂), molybdenum diselenide (MoSe₂), tungsten disulfide (WS₂), or tungsten diselenide (WSe₂)), or high-k material (e.g., Bi₂SeO₅ or Sb₂O₃). In one embodiment, the mask material comprises at least one of amorphous silicon dioxide (a-SiO₂), amorphous silicon (a-Si), amorphous silicon nitride (a-SiNₓ), amorphous carbon (a-carbon), hafnium oxide (HfO₂), aluminum oxide (Al₂O₃), hafnium zirconium oxide (HfZrO), titanium dioxide (TiO₂), zinc oxide (ZnO), iron oxide (Fe₂O₃), tin oxide (SnO₂), nickel oxide (NiO), or copper oxide (CuO).

In one extended embodiment, wherein the nucleus is a first nucleus and the single-domain monolayer is a first single-domain monolayer, the method further comprising the steps of: (g) waiting for an incubation period; (h) depositing another adatom of a third material on top of the first single-domain monolayer of at least one trench in the trench array, wherein a third binding energy between the second material and the third material is greater than the second binding energy between the mask material and the third material; (i) allowing the another adatom of the third material to selectively nucleate into a second nucleus on top of the first single-domain monolayer within the at least one trench in the trench array; and (j) growing the nucleus within the at least one trench in the trench array; and wherein the lateral dimensions associated with the trench geometry limit growth of the second nucleus to a second single-domain monolayer of the third material, and wherein the first single-domain monolayer and the second single-domain monolayer form a bilayer.

In one embodiment, the third material comprises one of graphene, carbon nanotube (CNT), hexagonal boron nitride (h-BN), metallic transition-metal dichalcogenide (e.g., vanadium disulfide (VS₂), vanadium diselenide (VSe₂), cobalt sulfide (CoS₂), cobalt selenide (CoSe₂), titanium disulfide (TiS₂), or titanium diselenide (TiSe₂)), semiconducting transition-metal dichalcogenide (e.g., molybdenum disulfide (MoS₂), molybdenum diselenide (MoSe₂), tungsten disulfide (WS₂), or tungsten diselenide (WSe₂)), or high-k material.

In one embodiment, the bilayer is a heterojunction bilayer where the second material and third material are different from each other. In another embodiment, the bilayer is a homojunction bilayer where the second material and third material are similar to each other.

In one embodiment, each of l and w are picked to have a value equal to a product of an incubation time of another nucleus of the second material on the single-domain monolayer and a growth rate of the second material. For example, when the measured lateral growth rate of WSe₂ and the incubation time of the 2^{nd} nucleation were ˜0.4 μm/min and 5 min, respectively, l and w are picked to have a value equal to 5 min×0.4 μm/min=2 μm. In such an embodiment, l and w are each picked to be 2 microns.

In another embodiment, the method further comprises the step of forming a semiconductor device (a valleytronics device, a forksheet field-effect transistor (FET), or a complementary FET) comprising the single-domain monolayer.

In one embodiment, before depositing the mask material on the substrate, the method comprises the step of depositing at least one of hafnium oxide (HfO₂), aluminum oxide (Al₂O₃), hafnium zirconium oxide (HZO), titanium dioxide (TiO₂), zinc oxide (ZnO), iron oxide (Fe₂O₃), tin oxide (SnO₂), nickel oxide (NiO), or copper oxide (CuO) on silicon to form the substrate.

In another embodiment, the present invention provides a method comprising the steps of: (a) providing a substrate of a first material, the first material having a first Gibbs free energy; (b) depositing a mask material on the substrate, the mask material having a second Gibbs free energy, the second Gibbs free energy higher than the first Gibbs free energy; (c) forming a trench array on the mask material, the trench array comprising a plurality of trenches, each trench having a trench geometry having lateral dimensions of l×w, where each of l and w is picked to have a maximum dimension of 2 μm and each trench having an exposed portion of the substrate surrounded by sidewalls formed of the mask material; (d) depositing an adatom of a second material on the exposed portion of the substrate; (e) allowing the adatom to selectively nucleate into a first nucleus within each trench in the trench array; (f) growing the first nucleus within each trench in the trench array; wherein the lateral dimensions associated with the trench geometry limit growth of the first nucleus to a first single-domain monolayer of the second material; (g) waiting for an incubation period; (h) depositing another adatom of a third material on top of the first single-domain monolayer of at least one trench in the trench array; (i) allowing the another adatom of the third material to selectively nucleate into a second nucleus on top of the first single-domain monolayer within the at least one trench in the trench array; and (j) growing the nucleus within the at least one trench in the trench array; wherein the lateral dimensions associated with the trench geometry limit growth of the second nucleus to a second single-domain monolayer of the third material, wherein the first single-domain monolayer and the second single-domain monolayer form a bilayer.

In one embodiment, the first material comprises one of hafnium oxide (HfO₂), aluminum oxide (Al₂O₃), hafnium zirconium oxide (HZO), titanium dioxide (TiO₂), zinc oxide (ZnO), iron oxide (Fe₂O₃), tin oxide (SnO₂), nickel oxide (NiO), or copper oxide (CuO).

In one embodiment, either the second material or the third material comprises one of graphene, carbon nanotube (CNT), hexagonal boron nitride (h-BN), metallic transition-metal dichalcogenide (e.g., vanadium disulfide (VS₂), vanadium diselenide (VSe₂), cobalt sulfide (CoS₂), cobalt selenide (CoSe₂), titanium disulfide (TiS₂), or titanium diselenide (TiSe₂)), semiconducting transition-metal dichalcogenide (e.g., molybdenum disulfide (MoS₂), molybdenum diselenide (MoSe₂), tungsten disulfide (WS₂), or tungsten diselenide (WSe₂)), or high-k material (e.g., Bi₂SeO₅ or Sb₂O₃).

In one embodiment, the mask material comprises at least one of amorphous silicon dioxide (a-SiO₂), amorphous silicon (a-Si), amorphous silicon nitride (a-SiNₓ), amorphous carbon (a-carbon), hafnium oxide (HfO₂), aluminum oxide (Al₂O₃), hafnium zirconium oxide (HfZrO), titanium dioxide (TiO₂), zinc oxide (ZnO), iron oxide (Fe₂O₃), tin oxide (SnO₂), nickel oxide (NiO), or copper oxide (CuO).

All combinations of the foregoing concepts and additional concepts discussed in greater detail below (provided such concepts are not mutually inconsistent) are part of the inventive subject matter disclosed herein. In particular, all combinations of claimed subject matter appearing at the end of this disclosure are part of the inventive subject matter disclosed herein. The terminology used herein that also may appear in any disclosure incorporated by reference should be accorded a meaning most consistent with the particular concepts disclosed herein.

FIGS. 2A-2D are images of WSe₂ grown in arrays of confined areas (trenches) of different widths for different periods using the process in FIG. 1B. FIGS. 2A and 2B show WSe₂ grown in 10 μm-wide trenches for 20 minutes and 30 minutes, respectively. FIGS. 2C and 2D show WSe₂ grown in 2 μm-wide trenches for 7 minutes and 10 minutes, respectively.

As shown in FIG. 2A, growing WSe₂ in 10 μm-wide trenches for 20 minutes (much longer than the five-minute second nucleation incubation time) led to multiple nuclei in some trenches. While about 70% of the trenches in FIG. 2A contained only a single WSe₂ triangle apiece, the other trenches contained multiple nuclei. Increasing the growth time to 30 minutes resulted in the formation of multidomain polycrystalline WSe₂ as shown in FIG. 2B. Substantial reduction of photoluminescence (PL) intensity was observed for the multidomain areas compared to the single-domain areas. Of trenches with multiple nuclei, 25% contained more than two nuclei at the edges while the rest had nuclei at the centers. As shown in FIGS. 2C and 2D, however, reducing the trench width to 2 μm yielded only a single nucleus per trench, regardless of the position of nucleation either for homogeneous nucleation at the center or for heterogeneous nucleation at the edge.

Without being bound by any particular theory, confined growth effectively suppresses additional heterogeneous nucleation in the trenches by reducing the size of the possible nucleation area. Further growth of the nucleus yields a single-crystalline ML that fills the entire corresponding trench as shown in FIGS. 2C and 2D. Because each confined WSe₂ ML originates from a single nucleus, every WSe₂ ML in the array of trenches is single-crystalline across the wafer. About 97% of the 2-μm-wide trenches were completely filled by WSe₂ during the incubation period for second nuclei on top of the first layer of WSe₂.

FIGS. 2E and 2F show Raman mapping at the E¹_{2g} peak position and photoluminescence (PL) mapping at 1.65 eV, respectively, of WSe₂ grown in the 2-micron-wide trenches. The height of each trench may be between 5 and 100 nm. These measurements confirm that the WSe₂ grown in these trenches is indeed ML WSe₂. The average of the full width at half maximum (FWHM) of the PL spectra of the single-domain WSe₂ in the trenches was measured to be about 55 meV at room temperature, which is similar to high-quality, single-domain WSe₂ flakes that are mechanically isolated from bulk WSe₂.

Measurements show that it is possible to grow another layer of WSe₂ on these single ML-WSe₂ arrays to obtain uniform homo-BLs, which are electrically superior to MLs. Each trench allowed only a single domain to be filled in each pocket as was shown in FIG. 1B. Further increasing the growth time resulted in the formation of single-domain BL-WSe₂ that completely filled up the trenches. In each trench, there was only a single additional WSe₂ nucleus regardless of the mode of nucleation; i.e., about 60% of the second nuclei were heterogeneous nucleation seeded from the sidewalls of the SiO₂ masks. This was additionally verified by the shift of the Raman spectra from A_{1g} peak (about 259.6 cm⁻¹) for a confined ML to the B¹_{2g} peak (about 308.5 cm⁻¹) for the confined BL. In addition, the PL spectra peak shift from 1.65 eV to 1.6 eV confirms the transition from direct-gap to indirect-gap.

Raman mapping at B¹_{2g} peak and PL mapping at 1.6 eV, shown in FIGS. 2G and 2H, respectively, verifies the presence of uniform wafer-scale BL-2D materials in the trenches across the entire wafer. FIGS. 2I and 2J show high-resolution transmission electron microscope (HRTEM) images of 0.8 nm-thick ML-WSe₂ and 1.6 nm-thick BL-WSe₂, respectively. Scanning tunneling electron microscope (STEM) images confirm that BL-WSe₂ was grown without strain at the center or edge of the SiO₂ trench. In addition, plan-view HAADF-STEM analysis revealed that BL-WSe₂ are epitaxially aligned as AA′ stacking.

Confined growth of single-domain, TMD homo- or hetero-BLs at precisely defined locations on a wafer makes it possible to use TMDs as CMOS channel materials. FIG. 3A shows arrays of field effect transistors (FETs) on BL-WSe₂ grown on a 2-inch wafer using the confined growth methods illustrated in FIGS. 1B and 1C. The wafer in FIG. 3A is a sapphire wafer with back-gated devices made using metal-induced transfer. Other substrates, including Si wafers with appropriate masking materials, and other top gating solutions are also possible.

FIG. 3B shows representative drain-source current-gate-source voltage (I_{ds}-V_{gs}) characteristics measured from one of the BL-WSe₂ FET arrays. The FETs exhibit an on/off current ratio of >10⁸, a subthreshold swing (SS) of 240.5 mV/dec, a maximum on-current (Iₒₙ) density of up to 155.8 μA μm⁻¹ and a field-effect mobility (μ^{eff}=gₘ L/WC_{g}V_{ds}, C_{g}=11.6 nF cm⁻²) of up to 103.5 cm² V⁻¹ s⁻¹, at V_{ds}=−1 V. FIG. 3C shows a saturation current of up to 465 μAμm⁻¹.

FIG. 3D shows the turn-on current/effective mobility characteristics of the arrays of WSe₂ FETs in FIG. 3A benchmarked against WSe₂ FETs made using other methods. The electrical properties of FETs fabricated with confined-growth ML-/BL-WSe₂ are comparable to the best properties reported for single-crystalline WSe₂-based FETs, and similar (or better) to those of as-exfoliated flake-based ML/BL-WSe₂ FETs as shown in FIG. 3E.

FIG. 3F shows a statistical analysis on the FET arrays with respect to the turn-on current Iₒₙ per width and effective mobility par. The FETs exhibited a Gaussian distribution in both Iₒₙ per width and μ_{eff}; the average and variation values are 89.9 μAμm⁻¹ and 17.3% for Iₒₙ density and 79.1 cm² V⁻¹ s⁻¹ and 24.1% for par, respectively. The 213 FETs fabricated with confined BL-WSe₂ were made with an estimated yield of 93.9%. In addition, FETs fabricated with confined ML-WSe₂ have electrical performance comparable to FETs fabricated with confined BL-WSe₂. The FETs fabricated with confined BL-WSe₂ exhibited performance comparable to those of flake-based FETs uniformly across the whole array.

Inventive confined growth techniques can also be used to make logic and memory. FIG. 4A shows single-crystalline TMDs (here, MoS₂) made on a 10 nm layer of amorphous HfO₂ deposited on a Si wafer with a SiO₂ mask that defines trenches that are about 1 μm wide. DFT calculations confirm that TMDs have higher binding energy on HfO₂ than on SiO₂. However, the difference in binding energies of sapphire and SiO₂ is larger than the difference in binding energies of HfO₂ and SiO₂. This may lead to a shorter incubation time between the first and second nucleations when growing TMDs in a SiO₂ mask on a HfO₂ surface. The reduced incubation time can be mitigated by reducing the size of trenches to 1 μm and adjusting the carrier gases and growth conditions to further enhance selectivity between HfO₂ and SiO₂.

As shown in FIGS. 4B and 4C, only one nucleation event occurs in each 1 μm trench. Further growth successfully fills up the trenches, resulting in single-crystalline ML-MoS₂ in confined regions of the amorphous HfO₂ surface. Layer-by-layer growth is also possible. The confined ML-/BL-MoS₂ on the HfO₂ substrate was used to make FETs for verifying the electrical characteristics of the confined ML-/BL-MoS₂. FIG. 4D shows transfer characteristics (Ids-Vas) measured from these fabricated ML/BL-MoS₂ FETs. The FETs exhibited a maximum Iₒₙ density of up to 86.7 μA μm⁻¹ (ML-MoS₂) and 129.3 μA μm⁻¹ (BL-MoS₂), a μ_{eff} of up to 62.2 cm² V⁻¹ s⁻¹ and 88.61 cm² V⁻¹ s⁻¹, (FIG. 4E), where C_{g_HfO2}=600 nF cm⁻² and V_{ds}=1 V. These MoS₂ FETs have electrical properties similar to those of single-crystalline MoS₂-based FETs made using other techniques.

Consecutive confined growth of single-domain MLs can be used to make hetero-BL TMD semiconductors. For example, ML-MoS₂ can be grown on arrays of single-domain ML-WSe₂. A single MoS₂ nucleus can be confined in a WSe₂-filled trench, with full area coverage, and grown to form a single-domain MoS₂/WSe₂ hetero-BL. Raman mapping and PL spectra confirmed uniform formation of MoS₂/WSe₂ hetero-BLs. In addition, the cross-sectional HAADF-STEM image in FIG. 4F shows a sharp van der Waals (vdW) heterointerface between the confined ML-MoS₂ and ML-WSe₂ without any alloying. A uniform heterointerface without secondary nucleation can be observed in the HAADF-STEM image at a low magnification.

FIG. 4G illustrates valleytronic performance of the MoS₂/WSe₂ hetero-BLs arrays. In particular, FIG. 4G shows valley-polarized carrier dynamics of confined ML-WSe₂ and hetero-BL (MoS₂/WSe₂) arrays characterized via ultrafast circular dichroism (CD) based on time-resolved pump-probe spectroscopy. In confined-growth ML-WSe₂, a valley lifetime (e.g., roughly tens of picoseconds) was observed by fast valley depolarization due to exchange interactions, whereas in confined hetero-BL, a longer valley lifetime (e.g., roughly hundreds of picoseconds) due to ultrafast charge separation was observed at 300 K. In addition, an increased valley lifetime (approximately nanoseconds) was also confirmed due to reduced phonon scattering at 77 K.

Confined-growth techniques can be used to synthesize arrays of single-domain 2D TMDs at the wafer scale. These confined-growth techniques enable ML-by-ML synthesis with critical Gibbs free energy difference, making it possible to fabricate homo-BL (WSe₂/WSe₂) and hetero-BL (MoS₂/WSe₂) array structures. In addition, arrays of confined-growth BL-WSe₂ transistor devices exhibited performance at the wafer-scale comparable to that of devices made with exfoliated WSe₂. Therefore, confined-growth techniques address difficulties in controlling the kinetics of 2D materials at a wafer-scale, which has been a major obstacle for 2D TMDs, and can be used for single-crystalline vdW integration at a large scale, providing a new route for building a 2D material-based electronics platform.

Simulations, Fabrication, and Measurements

DFT calculation for selective confined growth of TMDs. DFT calculations were performed using the Vienna Ab initio Simulation Package (VASP), which uses projector augmented wave (PAW) pseudopotentials and a plane-wave basis set. A generalized gradient approximation (GGA) of the Perdew-Burke-Ernzerhof (PBE) functional was used to describe the electronic exchange-correlation interaction. The valence electron configurations of W, Se, O, Al, and Si are 6s²5d⁴, 4s²4p⁴, 2s²2p⁴, 3s²3p¹, and 3s²3p², respectively. The energy cutoff for plane wave expansion was set at 420 eV. As large cells (lattice constant >10 Å) were used for the DFT calculations, the Brillouin zone was sampled by using a Γ-point only k-point grid. The surface binding interaction was investigated by placing the WO₃, Se, and WSe₂ clusters on top of a-HfO₂, Al₂O₃ (0001) and a-SiO₂ slabs, respectively. The HfO₂, SiO₂, and Al₂O₃ surfaces were passivated by H atoms to mimic the Ar/H₂ ambient growth environment. Amorphous HfO₂ and SiO₂ atomic structures were obtained by subjecting crystalline structures to melt-quench processes simulated by ab-initio molecular dynamics. Structures were optimized by relaxing top adsorbent atoms with fixed substrate atoms. The criterion for structure relaxation is the force exerted on the east atom less than 0.01 eV/Å. Electronic minimization occurred when the system energy difference between two consecutive iterations was smaller than 10⁻⁵ eV. The surface binding energy for adsorbent A on substrate B was calculated as E_{b}=E_{A/B}−E_{A}−E_{B}, where E_{A/B}, E_{A}, and E_{B} are the energies of the adsorbing system A/B, isolated adsorbent A, and substrate B, respectively.

Confined pattern fabrication. For confined growth of TMDs, LOR 3A and photoresist (PR; S1805) were coated on a sapphire substrate and patterned with an AS200 i-line stepper (AutoStep 200). A roughly 25-nm-thick layer of a-SiO₂ was deposited on a PR-patterned sapphire substrate with an e-beam evaporator. Then, to fabricate sapphire pockets (trenches), the SiO₂ pattern was lifted off with Remover PG (Kayaku Advanced Materials) and rinsed in acetone and isopropanol for 15 minutes each.

Synthesis of WSe₂ and MoS₂. Confined TMDs were synthesized in a quartz tube with a 4-inch diameter. 300 mg of Se or S powder was placed in (Zone I) and 30 mg of WO₃ or MoO₃ powder was placed in (Zone II), with the distance between zones fixed at 33 cm. The sapphire substrate patterned with SiO₂ was vertically loaded 6 cm behind the WO₃ or MoO₃ powder, and the front and back of the substrate were covered with quartz plates to reduce or minimize direct reaction.

Before synthesizing confined ML-WSe₂, the air in the quartz tube was removed with a vacuum pump. After closing the vacuum valve, a ratio of Ar (50 sccm)/H₂ (50 sccm) was used as the carrier gas to fill the tube before the atmospheric valve was opened. The ratio of Ar/H₂ was maintained continuously. The growth temperatures of (Zone I) and (Zone II) were heated at ramp rates of 15° C. min⁻¹ and 30° C. min⁻¹, respectively, then held at 450° C. (Zone I) and 890° C. (Zone II) for 10 min before cooling down naturally to room temperature.

For the confined BL-WSe₂, a second WSe₂ layer synthesis was performed with carrier gas having a ratio of Ar (35 sccm)/H₂ (65 sccm). For the confined heterostructure (MoS₂/WSe₂), MoS₂ synthesis was performed at 200° C. (Zone I) and 750° C. (Zone II) with ramp rates of 8° C. min⁻¹ and 30° C. min⁻¹, respectively. In particular, to improve the growth selectivity in the HfO₂ substrate, the size of the SiO₂ trenches was reduced to 1 μm and the overall flow rate of Ar/H₂ was increased from 100 sccm [Ar (50 sccm)/H₂ (50 sccm)] to 200 sccm [Ar (100 sccm)/H₂ (100 sccm)]. All reactions were performed at atmospheric pressure, and the TMD powders had purities of more than 99.99%.

Characterization of confined TMDs. Raman and PL spectra were measured using a Renishaw InVia Reflex micro-spectrometer with a 532 nm pump laser. The light was dispersed by a holographic grating with 2,400 grooves mm⁻¹. For Raman and PL mapping images, samples were scanned on an x-y piezo stage with laser illumination. SEM images were measured with an in-Lens detector using a high-resolution scanning electron microscope (ZEISS Merlin). The working distance was 6 mm at an accelerating voltage of 2 kV and a probe current of 70 pA. TEM characterization was performed using a (JEOL JEM-2100F) with an accelerating voltage of 200 kV and STEM (Titan Themis Z G3 Cs-Corrected) with an accelerating voltage of 60 kV. EDX line profiles were taken with the Velox software in STEM mode using the characteristic Mo Kα, S Kα, W Lα, and Se Kα X-ray signals. XPS spectra were measured with a magnesium Kα source (MultiLab 2000, Thermo VG), and the peak energies were calibrated by the C 1s peak at 284.8 eV. AFM morphology analysis was performed using an XE 100 (Park Systems Corp).

Device fabrication and electrical measurements. For device fabrication using confined ML-/BL-WSe₂, a 600 nm-thick Au film was deposited on confined WSe₂/sapphire by E-beam evaporation. The Au/WSe₂ stack was peeled off using a thermal release tape as a handling layer and transferred onto a 300 nm-thick SiO₂/heavily p-doped silicon wafer. The thermal release tape was removed on a hot plate at 120° C., followed by oxygen plasma treatment to remove tape residues from the Au film. Then, the Au film was etched with Au etchant and rinsed with de-ionized water (to compare the electrical characteristics, a few-layer WSe₂ flake was also transferred in the same way).

After the transfer of confined ML-/BL-WSe₂ on the SiO₂ substrate, alignment marks for electron-beam lithography (EBL) were patterned on the SiO₂ substrate using an optical lithography process, followed by the deposition of 2.5 nm-thick Ti and 7.5 nm-thick Au using an electron-beam evaporator. Then, drain and source contact regions with widths of 2 μm were patterned using EBL. For EBL photoresists, polymethyl methacrylate (PMMA) A4 and PMMA A6 were spin-coated at 3000 rpm and baked at 180° C. for 150 s. After developing the PMMA, 10 nm-thick Pt and 80 nm-thick Au layers were deposited using an electron-beam evaporator. Finally, areas except the source/drain contact metal regions was removed by a lift-off process. For device fabrication using confined ML-/BL-MoS₂ onto HfO₂, the same processes from patterning alignment marks for EBL to developing the PMMA were performed. Then, 10 nm-thick Ni and 80 nm-thick Au layers were deposited using an electron-beam evaporator, followed by lift-off.

The current-voltage characteristics were measured with an Agilent B2900A source/measure unit. All measurements were conducted at room temperature in air. In addition, 2-inch confined BL-WSe₂ was transferred onto a 300-nm-thick SiO₂/Si substrate with a size of 5.1×5.1 cm². Kelvin probe force microscopy (KPFM) confirmed highly uniform distribution of work functions (5.08 eV) on confined BL-WSe₂. Source and drain electrodes with a channel length (L_{CH}) of 0.7 μm were then integrated using platinum; a hole barrier height of 0.31 eV was estimated via modified Richardson plotting.

Time-resolved pump probe spectroscopy. Ultrafast CD was measured using time-resolved pump-probe spectroscopy to investigate valley-polarized carrier dynamics. A 100 kHz Yb-based regenerative amplifier system (Light Conversion PHAROS) provided femtosecond laser pulses, and a sequential optical parametric amplifier (ORPHEUS) produced wavelength-tunable pump and probe pulses resonant with the A-exciton resonance of WSe₂ with a pulse duration of 50 fs and spectral bandwidth of 50 meV. Samples on a cryostat were illuminated by the pump excitation pulses with a 40× objective lens. Pump-induced changes in probe reflectance was recorded as a function of time delay produced by mechanical translational stage and a lock-in amplifier. The polarization profiles of the pump and probe pulses were controlled individually by half-wave and quarter-wave plates. The signal was measured for pump and probe pulses exhibiting the same helicity of circular polarization (co-polarized) and opposite helicity of circular polarization (cross-polarized). Valley-dependent ultrafast CD responses shown in FIGS. 4F and 4G were acquired by difference between co-polarized, and cross-polarized pump-probe responses.

### CONCLUSION

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize or be able to ascertain, using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

Also, various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of,” “only one of,” or “exactly one of” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A method comprising the steps of:
(a) providing a substrate of a first material;
(b) depositing a mask material on the substrate;
(c) forming a trench array on the mask material, the trench array comprising a plurality of trenches, each trench having a trench geometry having lateral dimensions of l×w, where each of l and w is picked to have a maximum dimension of 2 μm and each trench having an exposed portion of the substrate surrounded by sidewalls formed of the mask material;
(d) depositing an adatom of a second material on the exposed portion of the substrate, wherein a first binding energy between the first material and the second material is greater than a second binding energy between the mask material and the second material;
(e) allowing the adatom to selectively nucleate into a nucleus within each trench in the trench array; and
(f) growing the nucleus within each trench in the trench array; and
wherein the lateral dimensions associated with the trench geometry limit growth of the nucleus to a single-domain monolayer of the second material.

2. The method of claim 1, wherein the first material comprises one of hafnium oxide (HfO₂), aluminum oxide (Al₂O₃), hafnium zirconium oxide (HZO), titanium dioxide (TiO₂), zinc oxide (ZnO), iron oxide (Fe₂O₃), tin oxide (SnO₂), nickel oxide (NiO), or copper oxide (CuO).

3. The method of claim 1, wherein the second material comprises one of graphene, carbon nanotube (CNT), hexagonal boron nitride (h-BN), metallic transition-metal dichalcogenide, semiconducting transition-metal dichalcogenide, or high-k material.

4. The method of claim 3, wherein the metallic transition-metal dichalcogenide is one of vanadium disulfide (VS₂), vanadium diselenide (VSe₂), cobalt sulfide (CoS₂), cobalt selenide (CoSe₂), titanium disulfide (TiS₂), or titanium diselenide (TiSe₂).

5. The method of claim 3, wherein the semiconducting transition-metal dichalcogenide is one of molybdenum disulfide (MoS₂), molybdenum diselenide (MoSe₂), tungsten disulfide (WS₂), or tungsten diselenide (WSe₂).

6. The method of claim 3, wherein the high-k material is one of Bi₂SeO₅ or Sb₂O₃.

7. The method of claim 1, wherein the mask material comprises at least one of amorphous silicon dioxide (a-SiO₂), amorphous silicon (a-Si), amorphous silicon nitride (a-SiNₓ), amorphous carbon (a-carbon), hafnium oxide (HfO₂), aluminum oxide (Al₂O₃), hafnium zirconium oxide (HfZrO), titanium dioxide (TiO₂), zinc oxide (ZnO), iron oxide (Fe₂O₃), tin oxide (SnO₂), nickel oxide (NiO), or copper oxide (CuO).

8. The method of claim 1, wherein the nucleus is a first nucleus and the single-domain monolayer is a first single-domain monolayer, the method further comprising the steps of:
(g) waiting for an incubation period;
(h) depositing another adatom of a third material on top of the first single-domain monolayer of at least one trench in the trench array, wherein a third binding energy between the second material and the third material is greater than the second binding energy between the mask material and the third material;
(i) allowing the another adatom of the third material to selectively nucleate into a second nucleus on top of the first single-domain monolayer within the at least one trench in the trench array; and
(j) growing the nucleus within the at least one trench in the trench array; and
wherein the lateral dimensions associated with the trench geometry limit growth of the second nucleus to a second single-domain monolayer of the third material, and
wherein the first single-domain monolayer and the second single-domain monolayer form a bilayer.

9. The method of claim 8, wherein the third material comprises one of graphene, carbon nanotube (CNT), hexagonal boron nitride (h-BN), metallic transition-metal dichalcogenide, semiconducting transition-metal dichalcogenide, or high-k material.

10. The method of claim 9, wherein the metallic transition-metal dichalcogenide is one of vanadium disulfide (VS₂), vanadium diselenide (VSe₂), cobalt sulfide (CoS₂), cobalt selenide (CoSe₂), titanium disulfide (TiS₂), or titanium diselenide (TiSe₂).

11. The method of claim 9, wherein the semiconducting transition-metal dichalcogenide is one of molybdenum disulfide (MoS₂), molybdenum diselenide (MoSe₂), tungsten disulfide (WS₂), or tungsten diselenide (WSe₂).

12. The method of claim 8, wherein the bilayer is a heterojunction bilayer where the second material and third material are different from each other.

13. The method of claim 8, wherein the bilayer is a homojunction bilayer where the second material and third material are similar to each other.

14. The method of claim 1, wherein forming the trench comprises etching through the mask material and partway into the substrate.

15. The method of claim 1, wherein each of/and w are picked to have a value equal to a product of an incubation time of another nucleus of the second material on the single-domain monolayer and a growth rate of the second material.

16. The method of claim 1, wherein each of/and w are picked to be 2 microns.

17. The method of claim 1, further comprising:
forming a semiconductor device comprising the single-domain monolayer.

18. The method of claim 17, wherein the semiconductor device comprises one of a valleytronics device, a forksheet field-effect transistor (FET), or a complementary FET.

19. The method of claim 1, further comprising, before depositing the mask material on the substrate:
depositing at least one of hafnium oxide (HfO₂), aluminum oxide (Al₂O₃), hafnium zirconium oxide (HZO), titanium dioxide (TiO₂), zinc oxide (ZnO), iron oxide (Fe₂O₃), tin oxide (SnO₂), nickel oxide (NiO), or copper oxide (CuO) on silicon to form the substrate.

20. A method comprising the steps of:
(a) providing a substrate of a first material, the first material having a first Gibbs free energy;
(b) depositing a mask material on the substrate, the mask material having a second Gibbs free energy, the second Gibbs free energy higher than the first Gibbs free energy;
(c) forming a trench array on the mask material, the trench array comprising a plurality of trenches, each trench having a trench geometry having lateral dimensions of l×w, where each of l and w is picked to have a maximum dimension of 2 μm and each trench having an exposed portion of the substrate surrounded by sidewalls formed of the mask material;
(d) depositing an adatom of a second material on the exposed portion of the substrate;
(e) allowing the adatom to selectively nucleate into a first nucleus within each trench in the trench array;
(f) growing the first nucleus within each trench in the trench array, wherein the lateral dimensions associated with the trench geometry limit growth of the first nucleus to a first single-domain monolayer of the second material;
(g) waiting for an incubation period;
(h) depositing another adatom of a third material on top of the first single-domain monolayer of at least one trench in the trench array;
(i) allowing the another adatom of the third material to selectively nucleate into a second nucleus on top of the first single-domain monolayer within the at least one trench in the trench array; and
(j) growing the nucleus within the at least one trench in the trench array;
wherein the lateral dimensions associated with the trench geometry limit growth of the second nucleus to a second single-domain monolayer of the third material, and
wherein the first single-domain monolayer and the second single-domain monolayer form a bilayer.

21. The method of claim 20, wherein the first material comprises one of hafnium oxide (HfO₂), aluminum oxide (Al₂O₃), hafnium zirconium oxide (HZO), titanium dioxide (TiO₂), zinc oxide (ZnO), iron oxide (Fe₂O₃), tin oxide (SnO₂), nickel oxide (NiO), or copper oxide (CuO).

22. The method of claim 20, wherein either the second material or the third material comprises one of graphene, carbon nanotube (CNT), hexagonal boron nitride (h-BN), metallic transition-metal dichalcogenide, semiconducting transition-metal dichalcogenide, or high-k material.

23. The method of claim 22, wherein the metallic transition-metal dichalcogenide is one of vanadium disulfide (VS₂), vanadium diselenide (VSe₂), cobalt sulfide (CoS₂), cobalt selenide (CoSe₂), titanium disulfide (TiS₂), or titanium diselenide (TiSe₂).

24. The method of claim 22, wherein the semiconducting transition-metal dichalcogenide is one of molybdenum disulfide (MoS₂), molybdenum diselenide (MoSe₂), tungsten disulfide (WS₂), or tungsten diselenide (WSe₂).

25. The method of claim 22, wherein the high-k material is one of Bi₂SeO₅ or Sb₂O₃.

26. The method of claim 20, wherein the mask material comprises at least one of amorphous silicon dioxide (a-SiO₂), amorphous silicon (a-Si), amorphous silicon nitride (a-SiNₓ), amorphous carbon (a-carbon), hafnium oxide (HfO₂), aluminum oxide (Al₂O₃), hafnium zirconium oxide (HfZrO), titanium dioxide (TiO₂), zinc oxide (ZnO), iron oxide (Fe₂O₃), tin oxide (SnO₂), nickel oxide (NiO), or copper oxide (CuO).

27. The method of claim 20, wherein the bilayer is a heterojunction bilayer where the second material and third material are different from each other.

28. The method of claim 20, wherein the bilayer is a homojunction bilayer where the second material and third material are similar to each other.
